(19) United States
(12) Patent Application Publication
(10) Pub. No.: US 2008/0022175 A1
(43) Pub. Date: Jan. 24, 2008

(54) Program memory having flexible data storage capabilities

(76) Inventors: Sanjeev Jain, Shrewsbury, MA (US); Mark B. Rosenbluth, Uxbridge, MA (US); Gilbert M. Wolrich, Framingham, MA (US); Jose S. Niell, Franklin, MA (US)

Correspondence Address: Grossman, Tucker, Perreault & Pfleger, PLLC;c/o Intellevate, P.O. Box 52050, Minneapolis, MN, 55402, US

(21) Appl. No.: 11/478,393

(22) Filed: Jun. 29, 2006

(51) Int. Cl. G01R 31/28

(52) U.S. Cl. 714/731

(57) ABSTRACT

A method according to one embodiment may include performing one or more fetch operations to retrieve one or more instructions from a program memory; scheduling a write instruction to write data from at least one data register into the program memory; and stealing one or more cycles from one or more of the fetch operations to write the data in the at least one data register into the program memory. Of course, many alternatives, variations, and modifications are possible without departing from this embodiment.

### FIELD

The present disclosure relates to program memory having flexible data storage capabilities.

### BACKGROUND

Network devices may utilize multiple threads to process data packets. In some network devices, each thread may concentrate on small sections of instructions and/or small instruction images during packet processing. Instructions (or instruction images) may be compiled and stored in a program memory. During packet processing, each thread may access the program memory to fetch instructions. In network devices that execute small instruction images, memory space in the program memory may go unused.

### BRIEF DESCRIPTION OF THE DRAWINGS

Features and advantages of embodiments of the claimed subject matter will become apparent as the following Detailed Description proceeds, and upon reference to the Drawings, wherein like numerals depict like parts, and in which:

FIG. 1 is a diagram illustrating one exemplary embodiment;

FIG. 2 depicts a flowchart of data write operations according to one embodiment;

FIG. 3 depicts a flowchart of data read operations according to another embodiment;

FIG. 4 is a diagram illustrating one exemplary integrated circuit embodiment; and

FIG. 5 is a diagram illustrating one exemplary system embodiment.

Although the following Detailed Description will proceed with reference being made to illustrative embodiments, many alternatives, modifications, and variations thereof will be apparent to those skilled in the art.

### DETAILED DESCRIPTION

Generally, this disclosure describes program memory that may be configured for data store capabilities. For example, a multiple threaded processing environment may include a plurality of small data registers for storing data and a larger program memory (e.g., control store memory) for storing instruction images. Some processing environments are tailored to execute small instruction images, and thus, such small instruction images may occupy only a portion of the program memory. As instructions are retrieved from the program memory and executed, data in the data registers may be loaded and reloaded to support data processing operations. To utilize unused memory space in the program memory, the present disclosure describes data write methodologies to write data stored in at least one of the data registers into the program memory. Additionally, the present disclosure provides data read methodologies to read data stored in the program memory and move that data into one or more data registers. Thus, unused space in the program memory may be used to store data that may otherwise be stored in registers and/or external, larger memory.

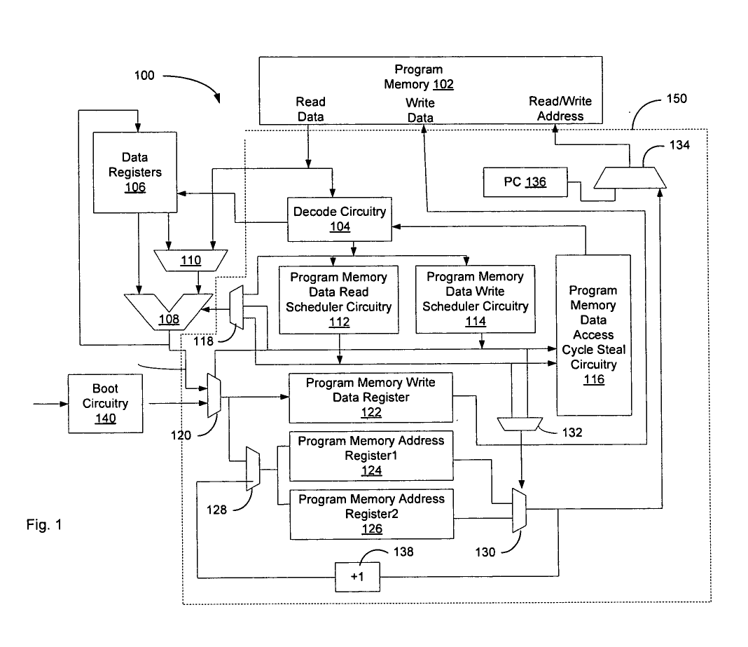

FIG. 1 is a diagram illustrating one exemplary embodiment 100. The embodiment of FIG. 1 depicts a read/write address path of a processor to read and write instructions and data into and out of a program memory 102. The components depicted in FIG. 1 may be part of, for example, a pipelined processor capable of fetching and issuing instructions back-to-back. This embodiment may also include a plurality of registers 106 configured to store data used during processing of instructions. The program memory 102 may be configured to store a plurality of instructions (e.g., instruction images). As will be described in greater detail below, this embodiment may also include control circuitry 150 configured to control read and write operations to and from memory 102, and to fetch and decode one or more instructions from program memory 102.

This embodiment may also include arithmetic logic unit (ALU) 108 configured to process one or more instructions from control circuitry 150. In addition, during processing of instructions, ALU 108 may fetch data stored in one or more data registers 106 and execute one or more arithmetic operations (e.g., addition, subtraction, etc.) and/or logical operations (e.g., logical AND, logical OR, etc.).

Control circuitry 150 may include decode circuitry 104 and one or more program counters (PC) 136. Decode circuitry 104 may be capable of fetching one or more instructions from program memory 102, decoding the instruction, and passing the instruction to the ALU 108 for processing. In general, program memory 102 may store processing instructions (as may be used during data processing), data write instructions to enable a data write operation to move data from the data registers 106 into the program memory 102, and data read instructions to enable a data read from the program memory 102 (and, in some embodiments, store that data in one or more data registers 106). When the embodiment of FIG. 1 is operating on one or more processing instructions, program counters 136 may be used to address memory 102 to fetch one or more instructions stored therein. In one exemplary embodiment, a plurality of program counters may be provided for use by a plurality of threads, and each thread may use a respective program counter 136 to address instructions stored in the program memory 102.

As an overview, control circuitry 150 may be configured to perform a data write operation to move data stored in one or more registers 106 into program memory 102. To write data from the data registers 106 into program memory 102, control circuitry 150 may be configured to schedule a data write operation. To prevent additional instructions from interfering with a scheduled data write operation, control circuitry 150 may also be configured to steal one or more cycles from one or more instruction fetch and/or decode operations to permit data to be written into the program memory 102. Additionally, control circuitry 150 may be further configured to read data from program memory 102, and write that data into one or more of the data registers 106. To read data from the program memory 102, control circuitry 150 may be configured to schedule a data read operation. To prevent additional instructions from interfering with a scheduled data read operation, control circuitry 150 may also be configured to steal one or more cycles from one or more instruction fetch and/or decode operations to permit data to be read from the program memory 102. These operations may enable, for example, the program memory 102 to be used as both an instruction memory space and a data memory space.

In operation, before a data write or data read instruction is read out of the program memory, decode circuitry 104 may receive an address load instruction, and may pass a value into at least one of the address registers 124 and/or 126 which may point to a specific location in the program memory 102. As will be described below, if a data write or data read instruction is later read from the program memory, the address registers 124 and/or 126 may be used for the data read and/or data write operations. Boot circuitry 140 may be provided to load instruction images (e.g., processing instructions, data write instructions and data read instructions) into program memory 102 upon initialization and/or reset of the circuitry depicted in FIG. 1.

### Program Memory Data Write Instructions

At least one of these instruction images stored on program memory 102 may include one or more instructions to move data stored in one or more data registers 106 into the program memory 102 (this instruction shall be referred to herein as a “program memory data write instruction”). When the program memory data write instruction is fetched by decode circuitry 104 and issued from memory 102, the program memory data write instruction may specify one of one or more program memory address registers to use as the “data write address” into the program memory 102. Or, the program memory data write instruction may include a specific address to use as the “data write address” in program memory 102 where the data is to be stored. Decode circuitry 104 may pass the data write address into at least one of the address registers 124 and/or 126. Upon receiving a program memory data write instruction, decode circuitry 104 may generate a request to program memory data write scheduler circuitry 114 to schedule a data write operation.

Data write scheduler circuitry 114 may be configured to schedule one or more data write operations to write data into the program memory 102. Upon receiving a request to schedule a data write into program memory 102, data write scheduler 114 may be configured to instruct the ALU 108 to pass the data output of one or more data registers 106 (as may be specified by the program memory data write instruction) into the program memory write data register 122. For example, data write scheduler circuitry 114 may be configured to schedule a data write to occur at a predetermined future instruction fetch cycle. To that end, data write scheduler circuitry 114 may control data access cycle steal circuitry 116 to “steal” at least one future instruction fetch cycle from the decode circuitry 104. When the stolen instruction fetch cycle occurs, data access cycle steal circuitry 116 may generate a control signal to decode circuitry 104 to abort instruction fetch and/or instruction decode operations to permit a data write into program memory 102 to occur.

During a data write operation, the address stored in register 124 and/or 126 may be used instead of, for example, an address defined by the program counters 136. To that end, the program counters 136 may be frozen during data write operations so that the program counters 136 do not increment until data write operations have concluded. Once the program memory 102 is addressed, the data stored in data register 122 may be written into memory, and data access cycle steal circuitry 116 may control decode circuitry 104 to resume instruction fetch and decode operations. Of course, multiple data write instructions may be issued sequentially. In that case, program memory data write scheduler circuitry 114 may schedule multiple data write operations by stealing multiple instruction fetch and/or decode cycles from decode circuitry 104. Further, for multiple data write operations, increment circuitry 138 may increment registers 124 and/or 126 to generate additional addresses to address the program memory 102.

A stolen instruction fetch cycle may be a fixed latency from when the data write instruction was fetched (e.g., issued), and may be based on, for example, the number of processing pipeline stages present. For example, decode circuitry 104 may use two cycles to fetch and a cycle to decode an instruction. A read of the data registers 106 may use another cycle. The ALU 108 may use another cycle to process the instruction and/or move data from or within the registers 106. Additional cycles may be used to store a data write address in register 124 and/or 126 and to move the data from one or more data registers 106 into register 122. Thus, in this example, data access cycle steal circuitry 116 may steal an instruction fetch cycle from decode circuitry 104 six or seven cycles after the data write instruction is fetched. Of course, these are only examples of processing cycles and it is understood that different implementations of the concepts provided herein may use a different number of cycles to process instructions. These alternatives are within the scope of the present disclosure.

Data access cycle steal circuitry 116 may control decode circuitry 104 to suspend instruction fetching operations for a cycle prior to writing data (stored in register 122) to the program memory 102 to permit, for example, read-to-write turnaround. A read-to-write turn around operation may enable control circuitry 150 to transition from read state (during which, for example, instructions may be read out of memory 102) to a write state (to permit, for example, data to be written into program memory 102). Additionally, data access cycle steal circuitry 116 may control decode circuitry 104 to suspend instruction fetching operations and/or instruction decode operations for a cycle after the last data write to the program memory 102 to permit, for example, write-to-read turnaround. A write-to-read turnaround operation may enable control circuitry 150 to transition from write state (during which data may be written into memory 102) to a read state (to permit, for example, additional instructions to be read out of program memory 102).

Multiplexer circuitry 110, 118, 120, 128, 130, 132 and 134 depicted in FIG. 1 may generally provide at least one output from one or more inputs, and may be controlled by one ore more of the circuit elements described above.

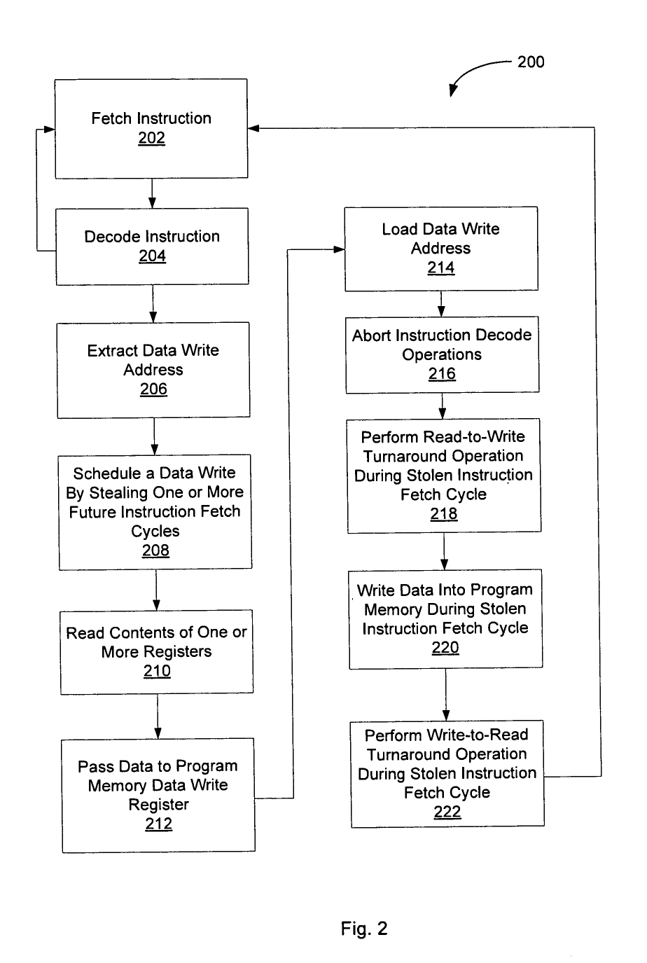

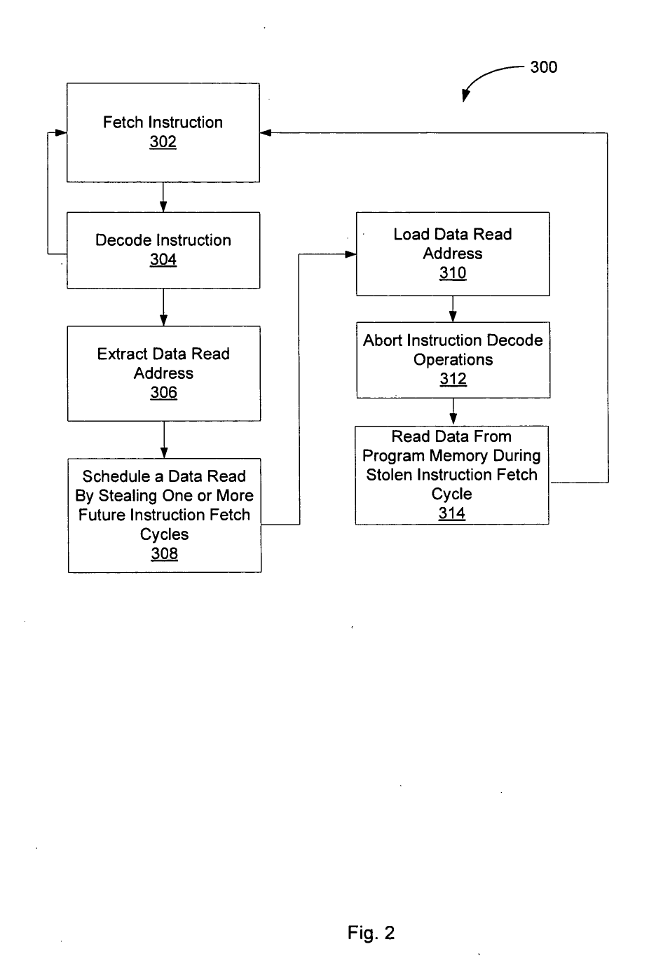

FIG. 2 depicts one method 200 to write data into the program memory. A processor may fetch an instruction 202, for example, from a program memory. The processor may decode the instruction 204 and determine, for example, that the instruction is a program memory data write instruction to write data into a program memory. In a pipelined environment, additional instructions may be fetched from the program memory in a sequential fashion and passed through a variety of execution and/or processing stages of the processor. The processor may extract a data write address 206. The data write address may point to a specific location to write data into the program memory. The data write address may be stored in a register for use during the data write operations. Once the data write address is known, the processor may schedule a data write by stealing one or more future instruction fetch cycles 208.

Before the data write occurs, the processor may read the contents of one or more data registers 210, and pass the data in the data register to a program memory data write register 212. To address the program memory for the data store location, the processor may load the data write address (as may be stored in one more registers) 214. The processor may also abort instruction decode and/or instruction fetch operations 216, for example, during one or more stolen instruction fetch cycles. Before data is moved from the program memory data write register into the program memory, the processor may perform a read-to-write turnaround operation during one or more stolen instruction fetch cycles 218. The processor may then write the data into the program memory during one or more stolen instruction fetch cycles 220. After data write operations have concluded, the processor may perform a write-to-read turnaround operation during an additional stolen instruction fetch cycle 220.

### Program Memory Data Read Instructions

With continued reference to FIG. 1, as stated above, program memory 102 may also include data read instructions to read data out of the program memory 102 (this instruction shall be referred to herein as a “program memory data read instruction”). To that end, circuitry 150 may be configured to read data that is stored in program memory 102 (as may occur as a result of the operations described above) and store the data in one or more data registers 106. The program memory data read instruction may specify one or more program memory address registers to use as the “data read address” into the program memory 102. Or, the program memory data read instruction may include a specific address (“data read address”) in program memory 102 where the data is stored. Decode circuitry 104 may pass the data read address into at least one of the address registers 124 and/or 126. Upon receiving a program memory data read instruction, decode circuitry 104 may generate a request to the program memory data read scheduler circuitry 112 to schedule a data read operation.

Data read scheduler circuitry 112 may be configured to schedule one or more data read operations to read data from the program memory 102. Upon receiving a request to schedule a data read from program memory 102, data read scheduler 112 may be configured to schedule a data read to occur at a predetermined future instruction fetch cycle. To that end, data read scheduler circuitry 112 may control data access cycle steal circuitry 116 to “steal” a future instruction fetch cycle from the decode circuitry 104. When the stolen instruction fetch cycle occurs, data access cycle steal circuitry 116 may generate a control signal to decode circuitry 104 to abort instruction decode operations and/or instruction fetch operations so that a data read from program memory 102 may occur. The stolen instruction fetch cycle may occur, for example, at a fixed latency from when the data read instruction was fetched (e.g., issued). To that end, and similar to the description above, the fixed latency may be based on, for example, the number of pipeline stages present in a given processing environment.

During a data read operation, the address stored in register 124 and/or 126 may be used instead of the address defined by the program counters 136. To that end, the program counters 136 may be frozen so that the program counters 136 do not increment until data read operations have concluded. Once the program memory is addressed 102, the data stored at the specified address in the program memory may be read out of the program memory. Data read scheduler circuitry 112 may also control the decode circuitry 104 to ignore the output of the program memory 102 while the data is read out. Data read scheduler circuitry 112 may also instruct ALU 108 to pass the data (from program memory 102) without modification and return the data to one or more data registers 106. Once data read operations have completed, data access cycle steal circuitry 116 may control decode circuitry 104 to resume instruction fetch and decode operations. Of course, multiple data read instructions may be issued sequentially. In that case, program memory data read scheduler circuitry 112 may schedule multiple data read operations by stealing multiple instruction fetch and/or decode cycles from decode circuitry 104. Further, for multiple data read operations, increment circuitry 138 may increment registers 124 and/or 126 to generate additional addresses to address the program memory 102.

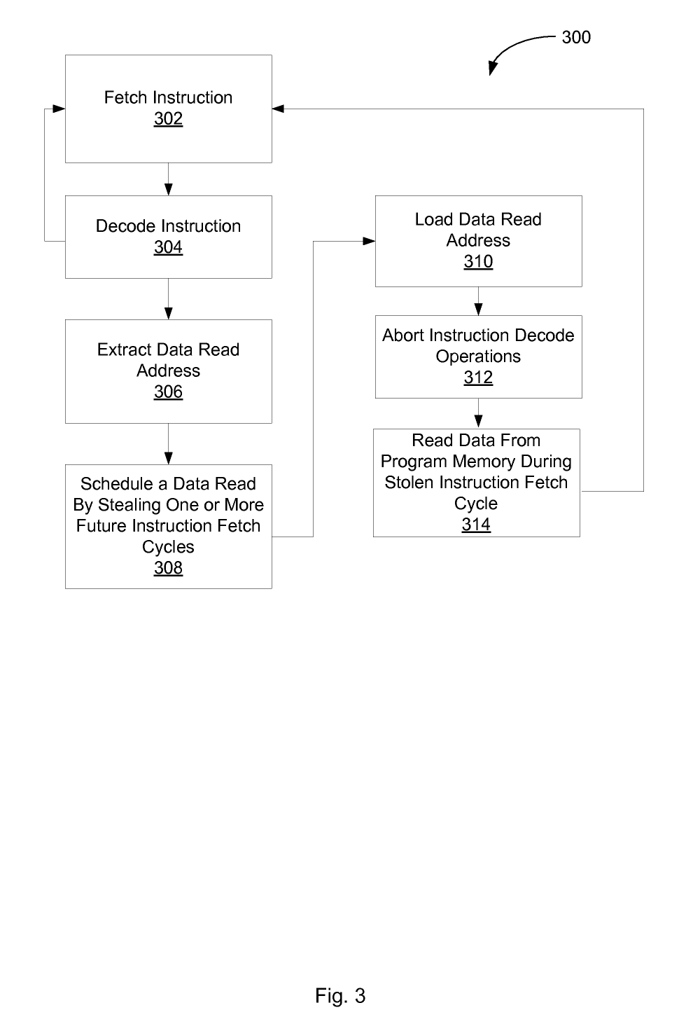

FIG. 3 depicts one method 300 to read data out of the program memory. The operations depicted in FIG. 3 may be performed by a processor, and are described in that context. A processor may fetch an instruction 302, for example, from a program memory. The processor may decode the instruction 304 and determine, for example, that the instruction is a program memory data read instruction to write data into a program memory. In a pipelined environment, additional instructions may be fetched from the program memory in a sequential fashion and passed through various processing stages of the processor. The processor may extract a data read address 306. The data read address may point to a specific location in the program memory to read data. The data read address may be stored in a register for use during the data read operations. The processor may schedule a data read by stealing one or more future instruction fetch cycles 208. The processor may load the data read address (as may be stored in one more registers) 310. The processor may also abort instruction decode and/or instruction fetch operations 312, for example, during one or more stolen instruction fetch cycles. The processor may then read the data from the program memory during one or more stolen instruction fetch cycles 314.

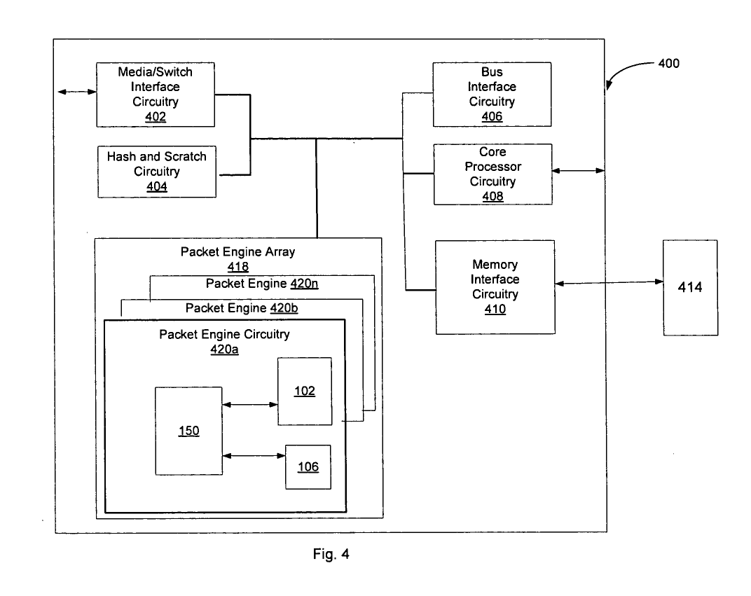

The embodiment of FIG. 1 and the flowcharts of FIGS. 2-3 may be implemented, for example, in a variety of multi-threaded processing environments. For example, FIG. 4 is a diagram illustrating one exemplary integrated circuit embodiment 400 in which the operative elements of FIG. 1 may form part of an integrated circuit (IC) 400. “Integrated circuit”, as used in any embodiment herein, means a semiconductor device and/or microelectronic device, such as, for example, but not limited to, a semiconductor integrated circuit chip. The IC 400 of this embodiment may include features of an Intel® Internet eXchange network processor (IXP). However, the IXP network processor is only provided as an example, and the operative circuitry described herein may be used in other network processor designs and/or other multi-threaded integrated circuits.

The IC 400 may include media/switch interface circuitry 402 (e.g., a CSIX interface) capable of sending and receiving data to and from devices connected to the integrated circuit such as physical or link layer devices, a switch fabric, or other processors or circuitry. The IC 400 may also include hash and scratch circuitry 404 that may execute, for example, polynomial division (e.g., 48-bit, 64-bit, 128-bit, etc.), which may be used during some packet processing operations. The IC 400 may also include bus interface circuitry 406 (e.g., a peripheral component interconnect (PCI) interface) for communicating with another processor such as a microprocessor (e.g. Intel Pentium®, etc.) or to provide an interface to an external device such as a public-key cryptosystem (e.g., a public-key accelerator) to transfer data to and from the IC 400 or external memory. The IC may also include core processor circuitry 408. In this embodiment, core processor circuitry 408 may comprise circuitry that may be compatible and/or in compliance with the Intel® XScale™ Core micro-architecture described in “Intel® XScale™ Core Developers Manual,” published December 2000 by the Assignee of the subject application. Of course, core processor circuitry 408 may comprise other types of processor core circuitry without departing from this embodiment. Core processor circuitry 408 may perform “control plane” tasks and management tasks (e.g., look-up table maintenance, etc.). Alternatively or additionally, core processor circuitry 408 may perform “data plane” tasks (which may be typically performed by the packet engines included in the packet engine array 418, described below) and may provide additional packet processing threads.

Integrated circuit 400 may also include a packet engine array 418. The packet engine array may include a plurality of packet engines 420a, 420b, . . . ,420n. Each packet engine 420a, 420b, . . . ,420n may provide multi-threading capability for executing instructions from an instruction set, such as a reduced instruction set computing (RISC) architecture. Each packet engine in the array 418 may be capable of executing processes such as packet verifying, packet classifying, packet forwarding, and so forth, while leaving more complicated processing to the core processor circuitry 408. Each packet engine in the array 418 may include e.g., eight threads that interleave instructions, meaning that as one thread is active (executing instructions), other threads may retrieve instructions for later execution. Of course, one or more packet engines may utilize a greater or fewer number of threads without departing from this embodiment. The packet engines may communicate among each other, for example, by using neighbor registers in communication with an adjacent engine or engines or by using shared memory space.

In this embodiment, at least one packet engine, for example packet engine 420a, may include the operative circuitry of FIG. 1, for example, the program memory 102, data registers 106 and control circuitry 150. Of course, ALU

Integrated circuit 400 may also include memory interface circuitry 410. Memory interface circuitry 410 may control read/write access to external memory 414. Memory 414 may comprise one or more of the following types of memory: semiconductor firmware memory, programmable memory, non-volatile memory, read only memory, electrically programmable memory, random access memory, flash memory (e.g., SRAM), dynamic random access memory (e.g., DRAM), magnetic disk memory, and/or optical disk memory. Either additionally or alternatively, memory 202 may comprise other and/or later-developed types of computer-readable memory. Machine readable firmware program instructions may be stored in memory 414, and/or other memory. These instructions may be accessed and executed by the integrated circuit 400. When executed by the integrated circuit 400, these instructions may result in the integrated circuit 400 performing the operations described herein as being performed by the integrated circuit, for example, operations described above with reference to FIGS. 1-3.

In addition to moving data from one or more data registers 106 into program memory 102, control circuitry 150 of this embodiment may be configured to read move data stored in memory 414 into the program memory 102, in a manner described above. Also, during a data read operation, control circuitry 150 may read data from the program memory 102 and write the data into memory 414.

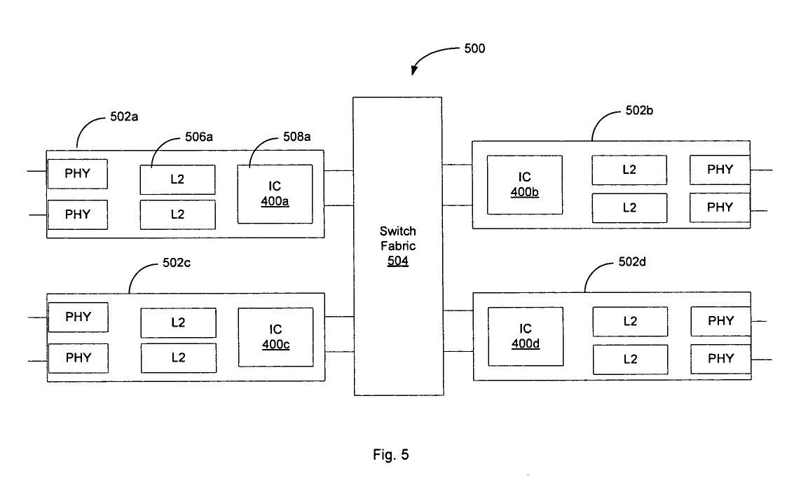

FIG. 5 depicts one exemplary system embodiment 500. This embodiment may include a collection of line cards 502a, 502b, 502c and 502d (“blades”) interconnected by a switch fabric 504 (e.g., a crossbar or shared memory switch fabric). The switch fabric 504, for example, may conform to CSIX or other fabric technologies such as HyperTransport, Infiniband, PCI-X, Packet-Over-SONET, RapidlO, and Utopia. Individual line cards (e.g., 502a) may include one or more physical layer (PHY) devices 508a (e.g., optic, wire, and wireless PHYs) that handle communication over network connections. The PHYs may translate between the physical signals carried by different network mediums and the bits (e.g., “0”-s and “1”-s) used by digital systems. The line cards may also include framer devices 506a (e.g., Ethernet, Synchronous Optic Network (SONET), High-Level Data Link (HDLC) framers or other “layer 2” devices) that can perform operations on frames such as error detection and/or correction. The line cards shown may also include one or more integrated circuits, e.g., 400a, which may include network processors, and may be embodied as integrated circuit packages (e.g., ASICs). In addition to the operations described above with reference to integrated circuit 400, in this embodiment integrated circuit 400a may also perform packet processing operations for packets received via the PHY(s) 408a and direct the packets, via the switch fabric 504, to a line card providing the selected egress interface. Potentially, the integrated circuit 400a may perform “layer 2” duties instead of the framer devices 506a.

As used in any embodiment described herein, “circuitry” may comprise, for example, singly or in any combination, hardwired circuitry, programmable circuitry, state machine circuitry, and/or firmware that stores instructions executed by programmable circuitry. It should be understood at the outset that any of the operative components described in any embodiment herein may also be implemented in software, firmware, hardwired circuitry and/or any combination thereof. A “network device”, as used in any embodiment herein, may comprise for example, a switch, a router, a hub, and/or a computer node element configured to process data packets, a plurality of line cards connected to a switch fabric (e.g., a system of network/telecommunications enabled devices) and/or other similar device. Also, the term “cycle” as used herein may refer to clock cycles. Alternatively, a “cycle” may be defined as a period of time over which a discrete operation occurs which may take one or more clock cycles (and/or fraction of a clock cycle) to complete.

Additionally, the operative circuitry of FIG. 1 may be integrated within one or more integrated circuits of a computer node element, for example, integrated into a host processor (which may comprise, for example, an Intel® Pentium® microprocessor and/or an Intel® Pentium® D dual core processor and/or other processor that is commercially available from the Assignee of the subject application) and/or chipset processor and/or application specific integrated circuit (ASIC) and/or other integrated circuit. In still other embodiments, the operative circuitry provided herein may be utilized, for example, in a caching system and/or in any system, processor, integrated circuit or methodology that may have unused memory resources.

Accordingly, at least one embodiment described herein may provide an integrated circuit (IC) that includes a program memory for storing instructions and at least one data register for storing data. The IC may be configured to perform one or more fetch operations to retrieve one or more instructions from the program memory. The IC may be further configured to schedule a write instruction to write data from said at least one data register into the program memory, and to steal one or more cycles from one or more fetch operations to move the data in at least one data register into the program memory.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1. An apparatus, comprising:
an integrated circuit (IC) comprising a program memory for storing instructions and at least one data register for storing data; said IC is configured to perform one or more fetch operations to retrieve one or more instructions from said program memory, said IC is further configured to schedule a write instruction to write data from said at least one data register into said program memory, and to steal one or more cycles from one or more said fetch operations to write said data in said at least one data register into said program memory.

2. The apparatus of claim 1, wherein:
said IC is further configured to schedule a read instruction to read said data from said program memory and to steal one or more clock cycles from one or more said fetch operations to read said data out of said program memory into at least one said data register, said IC is further configured to increment one or more program memory address registers after reading data out of said program memory.

3. The apparatus of claim 1, wherein:
said IC is further configured to steal at least one instruction fetch cycle to perform a read-to-write turnaround operation before execution of said write instruction to enable a transition from a read state to a write state.

4. The apparatus of claim 1, wherein:
said IC is further configured to steal at least one instruction fetch cycle to perform a write-to-read turnaround operation after said write instruction to enable a transition from a write state to a read state.

5. The apparatus of claim 1, wherein:
said IC is further configured to steal at least one instruction fetch cycle at a fixed latency from when the write instruction issues.

6. The apparatus of claim 2, wherein:
said IC is further configured to steal at least one instruction fetch cycle at a fixed latency from when the read instruction issues.

7. A method, comprising:
performing one or more fetch operations to retrieve one or more instructions from a program memory;
scheduling a write instruction to write data from at least one data register into said program memory; and
stealing one or more cycles from one or more said fetch operations to write said data in said at least one data register into said program memory.

8. The method of claim 7, further comprising:
scheduling a read instruction to read said data from said program memory; stealing one or more clock cycles from one or more said fetch operations to read said data out of said program memory into at least one said data register; and
incrementing one or more program memory address registers after reading data out of said program memory.

9. The method of claim 7, further comprising:
performing a read-to-write turnaround operation, during at least one stolen cycle, before execution of said write instruction to enable a transition from a read state to a write state.

10. The method of claim 7, further comprising:
performing a write-to-read turnaround operation, during at least one stolen cycle, after said write instruction to enable a transition from a write state to a read state.

11. The method of claim 7, wherein:
said stealing said at least one instruction fetch cycle occurs at a fixed latency from when the write instruction issues.

12. The method of claim 8, wherein:
said steal said at least one instruction fetch cycle occurs at a fixed latency from when the read instruction issues.

13. An article comprising a storage medium having stored thereon instructions that when executed by a machine result in the following:
performing one or more fetch operations to retrieve one or more instructions from a program memory;
scheduling a write instruction to write data from at least one data register into said program memory; and
stealing one or more cycles from one or more said fetch operations to write said data in said at least one data register into said program memory.

14. The article of claim 13, wherein said instructions that when executed by said machine results in the following additional operations:
scheduling a read instruction to read said data from said program memory; stealing one or more clock cycles from one or more said fetch operations to read said data out of said program memory into at least one said data register; and
incrementing one or more program memory address registers after reading data out of said program memory.

15. The article of claim 13, wherein said instructions that when executed by said machine results in the following additional operations:
performing a read-to-write turnaround operation, during at least one stolen cycle, before execution of said write instruction to enable a transition from a read state to a write state.

16. The article of claim 13, wherein said instructions that when executed by said machine results in the following additional operations:
performing a write-to-read turnaround operation, during at least one stolen cycle, after said write instruction to enable a transition from a write state to a read state.

17. The article of claim 13, wherein:
said stealing said at least one instruction fetch cycle occurs at a fixed latency from when the write instruction issues.

18. The article of claim 14, wherein:
said steal said at least one instruction fetch cycle occurs at a fixed latency from when the read instruction issues.

19. A system, comprising:
a plurality of line cards and a switch fabric interconnecting said plurality of line cards, at least one line card comprising:
an integrated circuit (IC) comprising a plurality of packet engines, each said packet engine is configured to execute instructions using a plurality of threads; said IC further comprising a program memory for storing instructions and at least one data register for storing data; said IC is configured to perform one or more fetch operations to retrieve one or more instructions from said program memory, said IC is further configured to schedule a write instruction to write data from said at least one data register into said program memory, and to steal one or more cycles from one or more said fetch operations to write said data in said at least one data register into said program memory.

20. The system of claim 19, wherein:
said IC is further configured to schedule a read instruction to read said data from said program memory and to steal one or more clock cycles from one or more said fetch operations to read said data out of said program memory into at least one said data register, said IC is further configured to increment one or more program memory address registers after reading data out of said program memory.

21. The system of claim 19, wherein:
said IC is further configured to steal at least one instruction fetch cycle to perform a read-to-write turnaround operation before execution of said write instruction to enable a transition from a read state to a write state.

22. The system of claim 19, wherein:
said IC is further configured to steal at least one instruction fetch cycle to perform a write-to-read turnaround operation after said write instruction to enable a transition from a write state to a read state.

23. The system of claim 19, wherein:
said IC is further configured to steal at least one instruction fetch cycle at a fixed latency from when the write instruction issues.

24. The system of claim 20, wherein:
said IC is further configured to steal at least one instruction fetch cycle at a fixed latency from when the read instruction issues.

25. The apparatus of claim 1, wherein:
said IC is further configured to increment one or more program memory address register after writing data into said program memory.

26. The method of claim 7, further comprising:
incrementing one or more program memory address register after writing data into said program memory.

27. The article of claim 13, wherein said instructions that when executed by said computer results in the following additional operations:
incrementing one or more program memory address register after writing data into said program memory.

28. The system of claim 19, wherein:
said IC is further configured to increment one or more program memory address register after writing data into said program memory.
